(19) United States
(12) Patent Application Publication
(10) Pub. No.: US 2024/0079580 A1
(43) Pub. Date: Mar. 7, 2024

(54) MIXED CATHODE UPCYCLING

(71) Applicant: Worcester Polytechnic Institute, Worcester, MA (US)

(72) Inventors: Yan Wang, Acton, WA (US); Xiaotu Ma, Worcester, MA (US)

(21) Appl. No.: 17/902,021

(22) Filed: Sep. 2, 2022

Related U.S. Application Data
(60) Provisional application No. 63/240,947, filed on Sep. 5, 2021.

(51) Int. Cl. H01M 4/525; C01G 53/00; C30B 9/00; C30B 29/22; H01M 10/54

(52) U.S. Cl. CPC H01M 4/525; C01G 53/44; C30B 9/00; C30B 29/22; H01M 10/54; H01M 2004/028

(57) ABSTRACT

A method for recycling secondary battery charge materials includes a one-step molten-salt process to upcycle mixed Ni-lean polycrystalline NMC cathodes into Ni-rich single-crystal NMC cathodes. The method includes receiving a recycling stream of charge materials from end-of-lifetime batteries, adding additional charge materials based on an upcycled battery chemistry intended for the upgraded, recycled battery, and sintering the combined charge materials for generating a single crystal charge material corresponding to the upcycled battery chemistry using a molten salt direct recycling process.

### RELATED APPLICATIONS

This patent application claims the benefit under 35 U.S.C. § 119(e) of U.S. Provisional Patent App. No. 63/240,947 filed Sep. 5, 2021, entitled “MIXED CATHODE UPCYCLING,” incorporated herein by reference in entirety.

### BACKGROUND

Electric vehicles (EV), including both plug-in and hybrid approaches, require substantial electrical storage in the form of a battery. Typically, a Li-ion battery (LIB) is favored by most, if not all, EV manufacturers due to storage density, high discharge rate and charge cycle longevity. Earlier battery technology used in previous generations of EVs is now resulting in end-of-life batteries that are based on older technology that may not be consistent with the performance of modern LIB s being used in new vehicles.

### SUMMARY

A method for recycling secondary battery charge materials is defined by a one-step molten-salt process to upcycle mixed Ni-lean polycrystalline NMC cathodes into Ni-rich single-crystal NMC cathodes. The method includes receiving a recycling stream of charge materials from end of lifetime batteries, adding additional charge materials based on an upcycled battery chemistry intended for the upgraded, recycled battery, and sintering the combined charge materials for generating a single crystal charge material corresponding to the upcycled battery chemistry using a molten salt direct recycling process. In an example configuration, the recycled battery chemistry is defined by an alternative ratio of active charge materials from the recycling stream of charge materials, such as NMC (Nickel, Manganese, Cobalt). Other battery chemistries and charge material ratios may be achieved by the molten salt approach outlined above.

Configurations herein are based, in part, on the observation that older, first generation EVs employ batteries are approaching an end of useful life as the charge material therein degrades in an ability to hold and deliver electrical energy (charge). Unfortunately, conventional approaches used in these earlier batteries suffer from the shortcoming of battery chemistries that are generally deemed obsolete or inferior by modern standards. These older cells often employ Lithium Manganese Oxide (LiMn₂O₄) or Lithium Cobalt Oxide (LiCoO₂), for example, which are impractical to separate into constituent cathode materials. Modern EV battery chemistries employ Nickel Manganese Cobalt (NMC) or Nickel Cobalt Aluminum (NCA) chemistries, using nickel rich cathode material, in contrast to the older nickel-lean (or nickel devoid) battery chemistries.

Accordingly, configurations herein substantially overcome the shortcomings present in recycling nickel-lean cathode material by providing a direct recycling approach using a molten salt as a fluxing agent for direct recycling of older charge materials into an upgraded (upcycled), single crystal formulation of NMC and other nickel rich cathode materials. Direct recycling avoids a need to separate constituent elements of the cathode materials, but rather the mixture including a fluxing agent allows addition of nickel and other virgin or recycled charge materials to modify the ratio of cathode material elements, and produces a substantially single crystal cathode material of the desired battery chemistry. The disclosed approach also encompasses so-called mixed cathode materials, where older nickel-lean cathode materials are mixed with NMC and other nickel rich formulations.

A method of forming a charge material for a recycled battery includes, in an example configuration, combining a recycling stream of a nickel-lean cathode material, a quantity of Ni based on a target nickel ratio for the recycled material, a quantity of Li salts, and a fluxing agent to form a Li salt mixture. The nickel quantity is based on the ratio of the desired, upcycled, nickel rich recycled cathode material. The fluxing agent includes an excess of Li for upgrading polycrystalline charge material particles into single crystal charge material particles. The Li salt mixture is then sintered to form single crystal cathode material having the target nickel ratio, and excess Li salt is rinsed from the upcycled cathode material powder. In other words, the target nickel ratio formed from the addition of Ni forms a single crystal cathode material when sintered with the lithium salt, the excess of which washes away after sintering. The fluxing agent may be defined by additional Li salt such as LiOH, but the fluxing agent may take other forms.

### BRIEF DESCRIPTION OF THE DRAWINGS

The foregoing and other objects, features and advantages of the invention will be apparent from the following description of particular embodiments of the invention, as illustrated in the accompanying drawings in which like reference characters refer to the same parts throughout the different views. The drawings are not necessarily to scale, emphasis instead being placed upon illustrating the principles of the invention.

FIG. 1 is a prior art process of battery recycling for nickel-lean battery chemistries;

FIG. 2 is a context diagram of nickel rich and mixed cathode upcycling as in configurations herein;

FIGS. 3A-3H show scanning electron microscopy (SEM) images of upcycled, single crystal cathode materials from the process of FIG. 2;

FIG. 4 shows a flowchart of single crystal upgrading of nickel lean cathode materials as described in FIGS. 2-3H;

FIGS. 5A-5F show electrochemical performance graphs of upcycled NMC cathode material as in FIGS. 2 and 3A-H;

FIGS. 6A-6C show performance of an example configuration for generating upcycled NMC622 cathode material according to the processes of FIGS. 2-4F;

FIGS. 7A-7B show SEM images of nickel lean NMC 111 to upcycled NMC 622; and

FIGS. 8A-8B show XRD images of the cathode materials of FIG. 6A.

### DETAILED DESCRIPTION

Depicted below are example configurations of cathode material upcycling of polycrystalline nickel-lean cathode material to single crystal nickel rich cathode materials. The incoming recycling stream as employed herein is referred to as nickel lean, as more modern cathode material chemistries employ much higher ratios of nickel. Generally, older charge materials such as LMO and LCO have no nickel, and older mixed cathode materials include NMC 111 mixed in, however the nickel content is in no greater molar ratio than any other cathode material metal, typically manganese, cobalt, aluminum, and of course, lithium. Nickel rich cathode material is often provided in several common ratios, such as NMC 532, NMC 622 and NMC 811, where the digits refer to the respective molar ratios of nickel, manganese and cobalt. These nickel rich cathode material chemistries employ nickel in a molar ratio greater than at least one other charge material metal, often more than half. The direct recycling approach, discussed in further detail below, allows the ratio of charge materials to be augmented through addition of pure stock of specific elemental compounds of the cathode material without separation of the other materials, typically manganese and cobalt.

Configurations depicted below are directed to older, polycrystalline cathode materials where age and repeated charge cycles have degraded the ability of the polycrystalline material to accept and deliver charge. However, the disclosed approach may be used for any suitable polycrystalline cathode material; NMC cathode materials are employed herein as an example. In conventional lithium ion batteries with polycrystalline NMC materials, cycling capacity fades quickly, especially for Ni-rich NMC cathode materials, because the polycrystalline NMC particles are easily cracked during cycling, which accelerates capacity fading. In addition, secondary particles have the disadvantages of a small surface area and large diffusion distance of lithium diffusion, which also tend to limit the performance.

Among recycling processes, direct recycling particularly attractive because it is typically more energy and materials efficient than pyrometallurgy and acid leach (hydrometallurgical) processes. Conventional direct recycling, however cannot modify the original composition of regenerated cathodes, and some of the older chemistries are lagging behind more modern formulations and are obsolete. Moreover, mixed cathode materials such as LiMn₂O₄ (LMO)+ NMC or LMO+LiCoO₂ (LCO), may be used in different applications, and the cathode mixture is impractical to be separated for EV usage.

Concurrently, as a direct strategy to eliminate the well-known detrimental grain-boundary fracturing phenomena found in these older chemistries, the single-crystal structure has excellent potential to be widely applied in the near future. In combination, configurations herein demonstrate a direct upcycling process using a simple molten-salt method to upcycle polycrystalline NMC111, LMO+LCO, and LMO+ NMC111 recycling streams into upgraded single-crystal NMC622 (USC-NMC622) and NMC811 (USC-NMC811). In contrast to the polycrystalline NMC622 (P-NMC622) counterpart, the specific capacity and cycling stability of USC-NMC622 are simultaneously improved. This methodology demonstrates a pathway towards sustainable development of LIB s.

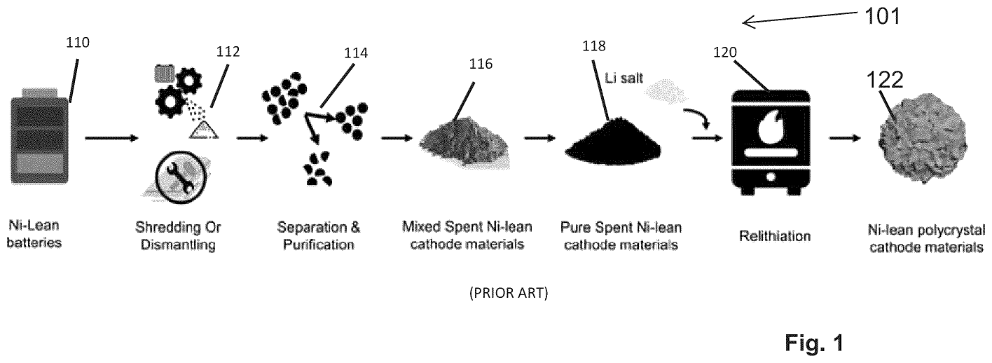

FIG. 1 is a prior art process of battery recycling for nickel-lean battery chemistries. Referring to FIG. 1, a conventional direct recycling process 101 is shown for relithiating spent cathode materials in the same charge material ratio as the source recycling stream. The source recycling stream includes end-of-life batteries 110 including nickel-lean cathode materials. Physical agitation (shredding and/or dismantling) at step 112 produces a granular stream of both anode and cathode charge materials. Other materials include the casing and current collectors, such as sheets of copper and aluminum, and the anode material, typically graphite or similar carbon forms. End-of-life batteries are generally those having exhausted or spent cathode material that has surpassed its serviceable tenure of effective charging and discharging capability. Other, newer batteries may also appear in the recycling stream, from vehicles retired for other reasons. In general, the incoming recycling stream may include a mix of cathode materials from unknown sources and limited predictable composition.

Separation and purification, at step 114, produces a mix of spent nickel-lean cathode material at 116. At step 118, pure cathode materials are combined with lithium salts for sintering at step 120, resulting in a nickel-lean conventional cathode material 122 of the same nickel content (and indeed the same chemistry) as the mixed cathode materials from 116. As described above, the result is a fresh, relithiated cathode material, but still composed of an outdated, conventional nickel-lean chemistry.

Therefore, to overcome the limitation of the traditional direct recycling, simplify the recycling process, and reduce the cost, this work demonstrates a direct upcycling process using a simple one-step molten salt method to upcycle polycrystalline NMC111, LMO+LCO, and LMO+ NMC111 recycling streams into upgraded single-crystal high nickel-containing NMC materials, such as NMC622 (USC-NMC622) and NMC811 (USC-NMC-811). In a specific example configuration, NiO is used to upgrade blended Ni-lean cathode materials to the desirable Ni-rich cathode materials such as NMC622, which results in a low cost and straightforward processing method. Other nickel compounds may be employed in alternate configurations. Moreover, the demonstrated increase of Ni content is significant because NMC111 has such a low and relatively outdated Ni content, and the upgraded material chemistry is one that is relevant for current and future applications. For example, the Ni content increases by 303.03% from NMC111 to NMC622, achieved via direct recycling. Furthermore, in contrast to traditional polycrystalline NMC622 (P-NMC622) counterpart, the specific capacity of USC-NMC622 improved from 17.72% at 2 C and 202.5% at 10 C, and the cycling stability simultaneously improved 27.32% under 5 C/5 C galvanostatic charge/discharge cycling.

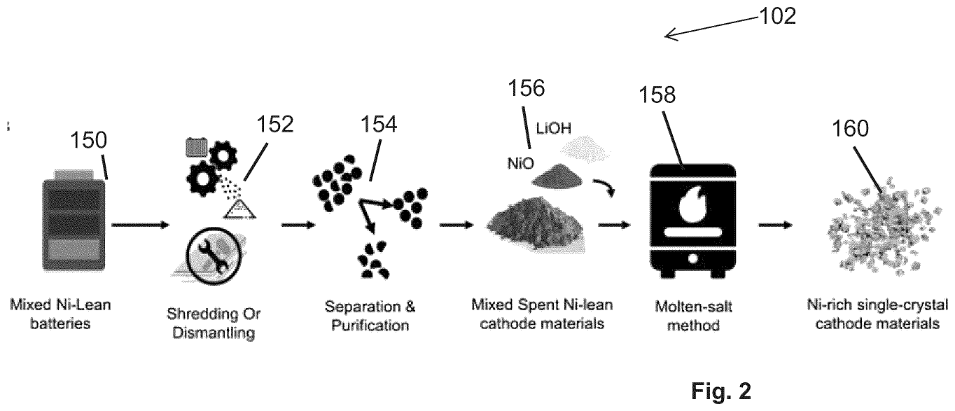

FIG. 2 is a context diagram of nickel rich and mixed cathode upcycling as in configurations herein. Referring to FIG. 2, the disclosed one-step molten salt upgrade process overcomes the limitations of feedstock on final product. The recycling stream 150 includes nickel-lean, exhausted batteries (cells), and undergoes physical dismantling 152 through shredding or grinding to form the granular mass for recycling.

At step 154, separation and purification includes separating copper and aluminum current collector materials from the particulate mass, and sieving particles of the nickel-lean cathode material from graphite defining the anode material. Since cathode material particles are smaller, on the order of 1 micron, sieving or filtering from larger 1 mm particles of anode material can be achieved with size based particle separation. The nickel-lean cathode materials remain in a solid, undissolved state for separation into mixed nickel-lean cathode materials at step 156. Additional nickel (NiO) and lithium salt (LiOH) is added for sintering at step 158, typically at around 900° C. Heating the Li salt mixture forms a molten salt defining a fluxing agent for upgrading the cathode material. The addition of Ni, other charge materials, and the Li for relithiation results in the single-step process where heating need be performed a single time for generating the single crystal cathode materials. Other ratio-adjusting cathode materials may also be added as needed. The sintered cathode material 160 is a nickel rich, single crystal formulation having a predetermined (based the added nickel) ratio such as NMC622 or NMC811.

Since the ratio of cathode materials is upgraded with added nickel and other materials, and sintered once, multiple high-heat steps for decomposition or ratio adjustment are avoided. Other advantages include changing the quantity and composition of the salt to control the morphology of the product to the desired characteristics, and the cathode material product can be doped without an additional high-temperature step. In configurations detailed below, commercial NMC111 is first employed as an example to verify feasibility. To obtain the best USC-NMC622, different amounts of excess of lithium source are added with NiO (nanosize) and marked as USC-NMC622—20%, USC-NMC622—30%, USC-NMC622—40%, and USC-NMC622—50%, with the percentage indicating the molar excess amount of lithium added.

A particular configuration based on the model of FIG. 2 proceeds as follows:
1. Spent mixed-type Ni-lean cathodes are mixed and ground with the appropriate amount NiO and LiOH.
2. 20 mol % LiOH and 10 mol % Li₂SO₄ were mixed as fluxing agents.
3. Then, the mixture was sintered at 900° C. for 10 h with a heating rate of 10° C./min under an oxygen atmosphere.
4. The obtained powders were washed with deionized water and dried, then loaded into an agate jar with agate balls. And the jar was fixed on a high-speed planetary mill and operated at the given condition. The grinding mode was clockwise and counterclockwise to produce materials with more homogeneous particle-size distributions.

This configuration is an example, and various other formulations of ratio-adjusting cathode materials and fluxing agents may be employed.

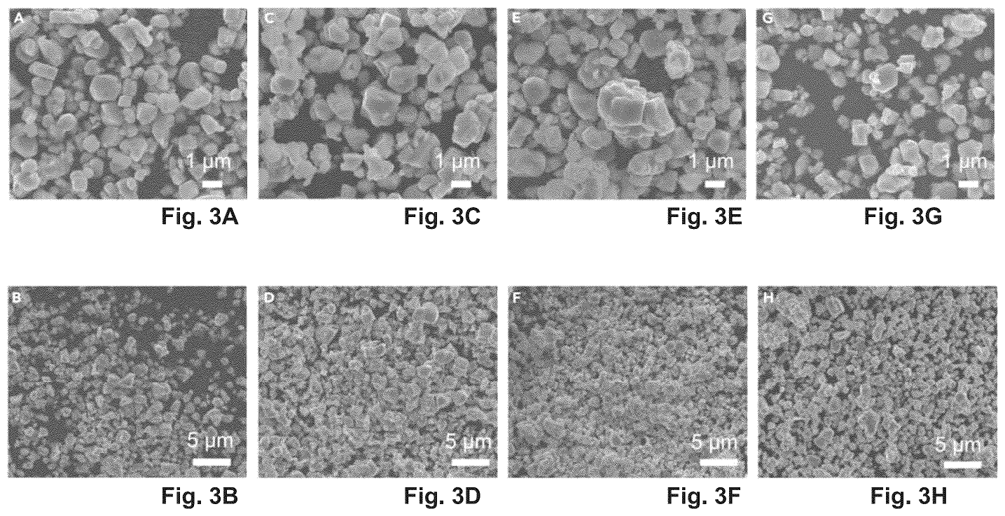

FIGS. 3A-3H show scanning electron microscopy (SEM) images of upcycled, single crystal cathode materials from the process of FIG. 2. Referring to FIGS. 3A-3H, morphology of USC-NMC622 with different amounts of excess LiOH included as the fluxing agent are shown at 1 um and Sum scale. FIGS. 3A-3B show USC-NMC622—20%, meaning 20% excess Li added as LiOH. FIGS. 3C-3D show USC-NMC622—30%, with 30% excess LiOH fluxing agent. FIGS. 3E-3F show USC-NMC622—40%; and FIGS. 3G and 3H show USC-NMC622—50% with 50% excess Li added. Performance specifications for these are illustrated further below.

TABLE I

| | Li | Ni | Mn | Co |
|---|---|---|---|---|
| USC-NMC622- | 1.066 | 0.607 | 0.181 | 0.212 |
| 20% | | | | |
| USC-NMC622- | 1.066 | 0.610 | 0.178 | 0.212 |
| 30% | | | | |
| USC-NMC622- | 1.043 | 0.610 | 0.179 | 0.211 |
| 40% | | | | |
| USC-NMC622- | 1.012 | 0.603 | 0.182 | 0.215 |
| 50% | | | | |
| P-NMC622 | 1.020 | 0.606 | 0.192 | 0.202 |

The images in FIGS. 3A-3H show the scanning electron microscopy (SEM) images of the determined optimal synthesis conditions for high-performance USC-NMC622. Substantially all secondary particles have been converted into single-crystal particles after the upgrading process, as noted from the clear boundaries between primary particles. Energy-dispersive spectroscopy (EDS) elemental mapping images demonstrate uniform distribution of transition metals (Ni, Mn, and Co). In addition, inductively coupled plasma mass spectrometry (ICP-MS) was used to confirm the composition of all samples (Table I). Table I reveals that all USC-NMC622 samples were successfully converted from commercial NMC111 with roughly the same stoichiometric ratio. All upgraded single-crystal cathodes and P-NMC622 exhibit excellent matching to the expected layered R-3m structure, without any detected peak shifts or impurity phases in the spectra. Mainly, the splitting of (104) and (101) peaks is not observed due to undetectable monoclinic distortion, meaning that highly ordered layered structures are obtained. Rietveld refinement was performed on all patterns to determine the crystal lattice parameters and the degree of cation mixing. The a-NaFeO₂ structure of space group R-3m is naturally employed as the standard pattern. All samples have similar a axis parameters and lattice volume. However, USC-NMC622-20% has the smallest lattice volume and lowest cation mixing of Ni in the Li layer with only 2.38%, significantly lower than that of P-NMC622 (5.06%). The lattice parameters (a, c) of USC-NMC622—20% are slightly smaller than those of other samples, attributed to the increased content of Ni³⁺ with smaller ionic radius and resulting in a lower cation mixing. Further, the cation mixing increases with the increase in the LiOH amount. Thus, the results may encourage additional configurations based on the effects of molten salt percentage on final lattice parameters.

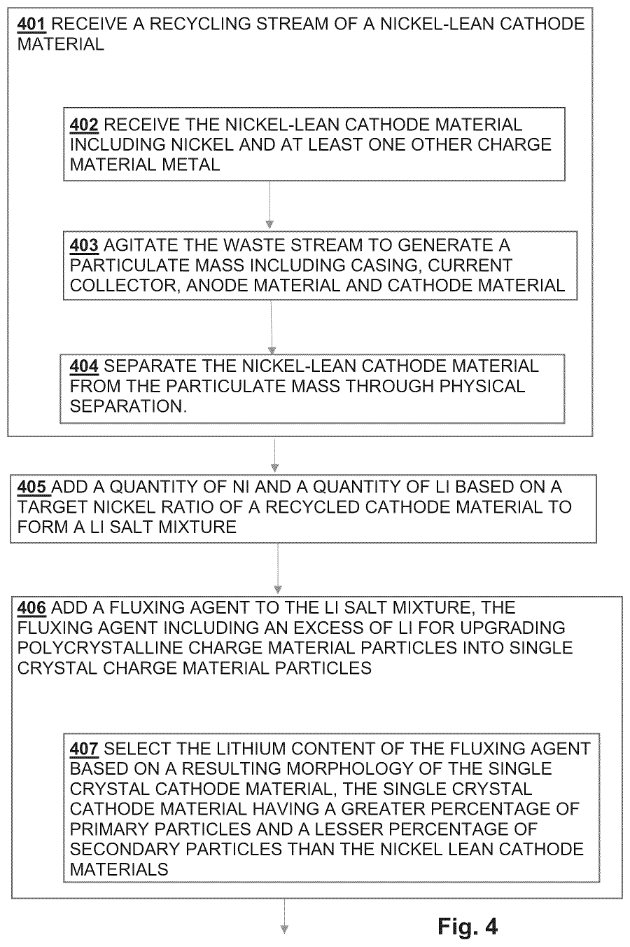

FIG. 4 shows a flowchart of single crystal upgrading of nickel lean cathode materials as described above. Referring to FIGS. 2-4, at step 401, the method of forming a single crystal upcycled charge material for a recycled battery, receiving a recycling stream of a nickel-lean cathode material. End-of-life and older, first generation EV batteries were often based on the nickel-lean chemistries. Depending on the source, this may include receiving the nickel-lean cathode material comprised of nickel and at least one other charge material metal, as shown at step 402. Cobalt, Aluminum and Manganese may also be found in such recycling streams, however the increase in the nickel content has been the most substantial improvement in recent LIB s. Crushing and/or grinding are used for agitating the waste stream to generate a particulate mass including casing, current collector, anode material and cathode material, as depicted at step 403. A combined “black mass” including anode materials, casing and current collectors remains comingled at this stage. Particulate sizes allow for separation of the nickel-lean cathode material from the particulate mass through physical separation, as disclosed at step 404. Sieving, filtering and other suitable approaches to isolating the cathode material suffices, as opposed to leaching or other hydrometallurgical approaches that require dissolution of cathode materials, typically via strong acid.

Molar equations and stoichiometric approaches can be used to determine elemental quantities for a target nickel ratio of a desired recycled battery chemistry, such as NMC622 or NMC811. A quantity of Ni and a quantity of Li is added based on the target nickel ratio of a recycled cathode material to form a Li salt mixture, as depicted at step 405. A basic configuration adjusts only nickel, using NiO, however the ratio of other cathode materials may also be adjusted/added. Lithium is in the form of LiOH, however other forms may suffice.

After computing the quantities of Li and Ni, an additional amount of Li is added. This includes adding a fluxing agent to the Li salt mixture, as depicted at step 406, such that the fluxing agent includes an excess of Li for upgrading polycrystalline charge material particles into single crystal charge material particles. Various percentages of Li may be employed, such as 20%, 30% 40% and 50%. The Li content of the fluxing agent is selected based on a resulting morphology of the single crystal cathode material, as disclosed at step 407. In general, the single crystal cathode material has a greater percentage of primary particles and a lesser percentage of secondary particles than the nickel lean cathode materials.

Following addition of the Li salt, nickel, and optionally other cathode materials to form the Li salt mixture, the Li salt mixture is sintered, as depicted at step 408, to form the single crystal cathode material having the target nickel ratio. After sintering, the excess lithium salt remains, depending on the quantity employed as the fluxing agent. Following sintering, the resulting cathode powder defining the single crystal cathode material is rinsed for removing excess, soluble lithium salt remaining, as depicted at step 409. The rinsed, single crystal cathode material is then agitated via ball milling or similar treatment for granular uniformity, as depicted at step 410. Agitation is for granular uniformity of the single crystal cathode material powder; it is not for breaking secondary particles as that has already been attained. Substantially all the secondary particles have now been upgraded into a single crystal (primary particle) morphology. The upgrading to form the single crystal cathode material results in converting at least 90% of the secondary particles in the nickel-lean cathode material to primary particles in the single crystal cathode material, however the actual percentages may vary and may be substantially higher.

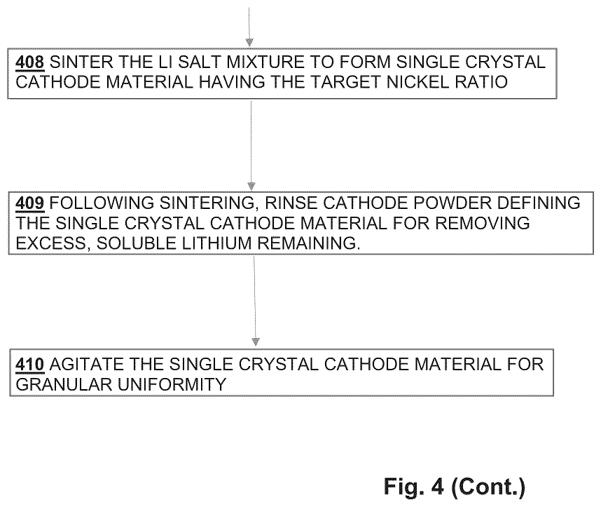

FIGS. 5A-5F show electrochemical performance graphs of upcycled NMC cathode material as in FIGS. 2 and 3A-H. FIGS. 5A-5F show performance variations across incremental changes of excess lithium salt (LiOH, in the disclosed examples) used. The target nickel ration sought is defined by NMC 622 as the desired recycling outcome. Upcycled material is designated with 501 and the percentage of excess lithium used as the fluxing agent, as in 501—20 for 20%, 501—30 for 30%, 501—40 for 40%, 501—50 for 50%, and 501-P for polycrystalline (non-upcycled) material.

The electrochemical performance of different USC-NMC622 and P-NMC622 cells was evaluated by half cells at the potential between 2.5 and 4.3 V (versus Li/Li⁺). As shown in FIG. 5A, all USC-NMC622 samples exhibit a higher initial discharge capacity compared with P-NMC622 at C/10 (1 C=175 mAh/g). FIG. 5B confirms that all USC-NMC622 samples have a similar discharge capacity at low rate (<=1 C) and much better performance at the high rate (2-10 C) with an error bar compared with P-NMC622. Significantly, the average specific capacity of all USC-NMC622 is ˜17.72% higher than that of P-NMC622 at 3 C and ˜36.36% better than that of P-NMC622 at 5 C. Furthermore, except for USC-NMC622—50%, the other USC-NMC622 samples show ˜202.5% greater capacity than P-NMC622 at 10 C. These results indicate that different amounts of Li salt could significantly affect the performance of upgraded single-crystal Ni-rich cathode materials, which opens a direction to conduct more research on the effect of different Li salts and how their respective amounts contribute to the electrochemical performance. In terms of overall rate performance, USC-NMC622—20% offers the best performance. Thus, it is chosen to further test cycling performance at 0.5 C in FIG. 5C. USC-NMC622—20% displays a similar capacity retention to P-NMC622 after 280 cycles (80.10% versus 79.19%).

Impressively, the cycling performance of USC-NMC622—20% under 5 C/5 C charging/discharging current rate is improved significantly. For P-NMC622, only 50.27% of its initial capacity remains after 100 cycles. Meanwhile, an astonishing 77.59% of initial capacity is retained by USC-NMC622—20%, which is an improvement of 27.32% compared with P-NMC622 (FIG. 5D). The cyclic voltammetry (CV) curves of P-NMC622 and USC-NMC622—20% were obtained between 2.8 and 4.6V (versus Li/Li+), as shown in FIGS. 5E-5F. The weak side peak around 4.3 V in the CV curves of P-NMC622 and USC-NM622—20% possibly corresponds to the Ni-rich content in both samples. Besides, the broader peak of USC-NMC622—20% indicates larger polarization than its counterpart P-NMC622, which can be attributed to the smaller particle size, leading to more contact surface area between single-crystal cathodes and electrolytes.

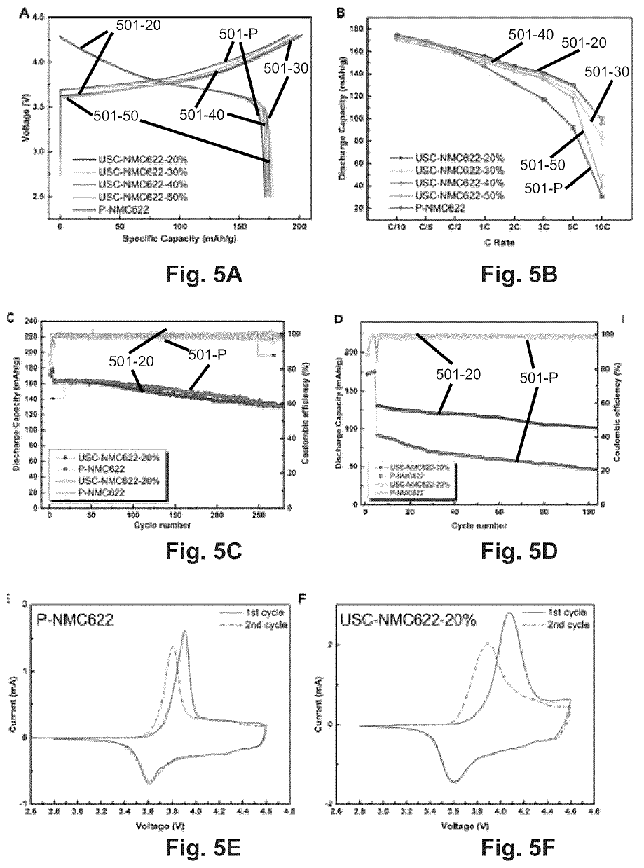

FIGS. 6A-6C show performance of an example configuration for generating upcycled NMC622 cathode material according to the processes of FIGS. 2-5F. FIG. 6A depicts an electron diffraction pattern of a selected area of USC-NMC622-LMO+ NMC111. The resulting single crystal, dense particles are consistent with FIG. 6A, and exhibit homogenous distribution of Ni, Mn, and Co. FIGS. 6B and 6C show a comparison of the electrochemical performance of P-NMC111, P-NMC622, and USC-NMC622-LMO+ NMC111. In FIG. 6B, rate performance comparison between P-NMC111, P-NMC622, and USC-NMC622-LMO+ NMC111 are shown. FIG. 6C shows cycle performance comparison under 5 C/5 C charging/discharging current between P-NMC111, P-NMC622, and USC-NMC622-LMO+ NMC111.

The rate performance of USC-NMC622-LMO+ NMC111 is significantly improved from P-NMC111 and LMO, where the discharge capacity at low rates is comparable with that of P-NMC622, but when the rate is over 2 C, the discharge capacity of USC-NMC622-LMO+ NMC111 is higher than that of P-NMC622. Further, the cycle performance is also better than that of P-NMC111 and P-NMC622. Additionally, a coating layer was observed in P-NMC622, and the upcycled sample does not have any coating or doping. Thus, it is worth noting that the low content Co, which is because of extra Mn from LMO, does not harm the upcycled sample's performance and the single-crystal structure can improve the cycle performance to a certain extent.

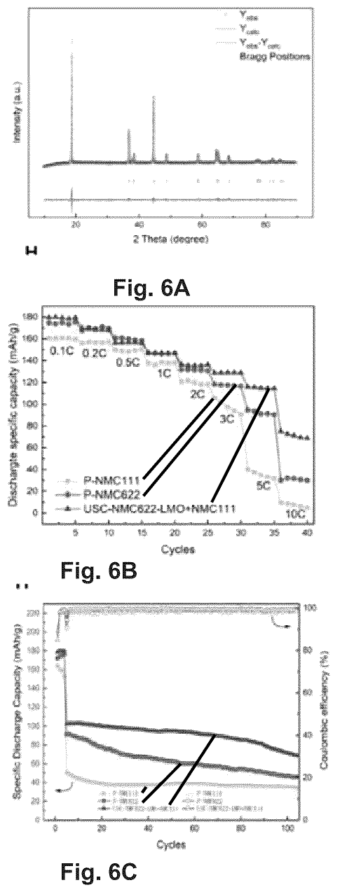

Furthermore, USC-NMC622-Spent is also achieved with the same method when applied to spent NMC111. FIGS. 7A-7B show SEM images of nickel lean NMC 111 to upcycled NMC 622. In FIG. 7A, spent NMC111 shows cracks on the secondary particles, reducing the difficulty of breaking them into single-crystal particles. FIG. 7B shows a larger particle size because of the difference of primary particle morphology between commercial NMC111 and spent NMC111.

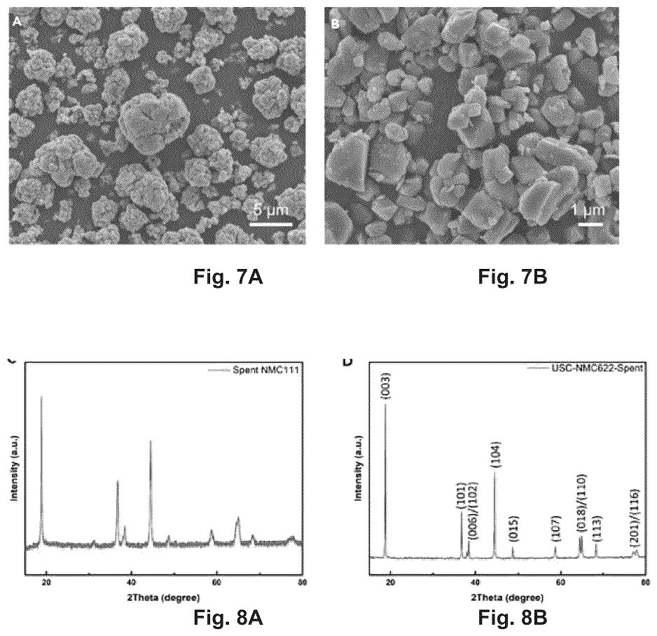

FIGS. 8A-8B show XRD images of the cathode materials of FIG. 7A. FIG. 8A reveals a lower (003)/(104) ratio, indicating a higher degree of cation mixing. Also, the peak splitting of (006)/(012) and (018)/(110) planes is reduced, corresponding to the reduced crystallinity of the layered structure in spent NMC111. After the upcycling process, the doublet peak splitting of the (006)/(012) and (018)/(110) planes is increased, and the ratio of (003)/(104) is also increased, indicating that a highly ordered layered structure and lower cation mixing was recovered in USC-NMC622-Spent (FIG. 8B).

### Example 1—Upgrading NMC111 to Single-Crystal NMC622

First, 5.184 mmol of commercial NMC111 was manually mixed with 3.456 mmol of NiO and 3.456 mmol of LiOH. Then, 20, 30, 40, and 50 mol % excess of LiOH and 10 mol % of Li₂SO₄ were added as fluxing agents. Then, the mixture was sintered 900° C. for 10 h with a heating rate of 10° C./min under an oxygen atmosphere. The obtained powders were washed with deionized water and dried and then loaded into an agate jar with agate balls. The jar was fixed on a high-speed planetary mill and operated under the given condition. The grinding mode was clockwise and counterclockwise to produce materials with more homogeneous particle-size distributions.

### Example 2—Upgrading NMC111 to Single-Crystal NMC811

First, 5.184 mmol of commercial NMC111 was manually mixed with 12.096 mmol of NiO and 12.096 mmol of LiOH. Then, 20 mol % excess of LiOH and 10 mol % of Li₂SO₄ were added as fluxing agents. Then, the mixture was sintered at 900° C. for 10 h with a heating rate of 10° C./min under an oxygen atmosphere. The obtained powders were then subjected to the same ball-milling procedure as above.

### Example 3—Upgrading LMO+ NMC111 and LMO+LCO to Single-Crystal NMC622

First, 20 wt % of LMO was mixed with NMC111. Then, LMO and LCO were mixed in a 1:1 weight ratio. Then, the appropriate amount of NiO and LiOH was added and ground. Next, 20 mol % LiOH and 10 mol % Li₂SO₄ were mixed as fluxing agents. Afterward, the mixture was sintered under the same conditions and ball-milling procedures as above.

### Example 4—Upcycling Spent NMC111 to Single-Crystal NMC622

5.207 mmol spent NMC111 was manually mixed with 3.468 mmol NiO and 3.468 mmol LiOH, and 20 mol % excess of LiOH and 10 mol % Li₂SO4 were added as fluxing agents. Then, the mixture was sintered under the same conditions and ball-milling procedures as above.

The disclosed approach demonstrates a simple one-step molten-salt method to upcycle mixed Ni-lean polycrystalline NMC cathodes into Ni-rich single-crystal NMC cathodes. The desired composition and highly ordered layered structure were achieved, leading to higher capacity and comparable cycling performance with the commercial polycrystalline counterparts. More notably, these configurations provide a solution to the limitations of the traditional direct recycling process with an ability to upcycle and accommodate the recycling of mixed cathode materials. Furthermore, the direct upcycling process can generate recycled products that can keep abreast of the market demand to realize the genuinely sustainable development and production of LIB s.

While the system and methods defined herein have been particularly shown and described with references to embodiments thereof, it will be understood by those skilled in the art that various changes in form and details may be made therein without departing from the scope of the invention encompassed by the appended claims.

What is claimed is:

1. A method of forming a single crystal cathode material, the method comprising:
i) combining:
a quantity of Ni,
a quantity of Li salts,
a fluxing agent, and
a recycling stream of a nickel-lean cathode material to form a Li salt mixture;
wherein the quantity of Ni is based on a target nickel ratio of a recycled cathode material and the fluxing agent includes an excess of Li salts; and
ii) sintering the Li salt mixture to form the single crystal cathode material having the target nickel ratio.

2. The method of claim 1, wherein the single crystal cathode material has a greater percentage of primary particles and a lesser percentage of secondary particles than the nickel lean cathode material.

3. The method of claim 1 further comprising heating the Li salt mixture to form a molten salt defining the fluxing agent, the heating performed a single time for generating the single crystal cathode materials.

4. The method of claim 1 further comprising, following sintering, rinsing the single crystal cathode material for removing excess, soluble lithium salts.

5. The method of claim 4 further comprising agitating the single crystal cathode material for granular uniformity.

6. The method of claim 1, wherein the recycling stream of the nickel-lean cathode material includes nickel and at least one other charge material metal.

7. The method of claim 2 wherein at least 90% of the secondary particles in the nickel-lean cathode material are converted to primary particles in the single crystal cathode material.

8. The method of claim 1 further comprising:
agitating an end-of-life battery waste stream to generate a particulate mass including casing, current collector, anode material and cathode material, and
separating the recycling stream of nickel-lean cathode material from the particulate mass through physical separation.

9. The method of claim 8 further comprising:
separating copper and aluminum current collector materials from the particulate mass; and
sieving particles of the nickel-lean cathode material from graphite defining the anode material.

10. The method of claim 1 wherein the nickel-lean cathode material remains in a solid, undissolved state.

11. In a battery recycling environment for receiving a recycling stream of end-of-life batteries formed from nickel-lean formulations, a non-leaching process for upcycling a nickel-lean cathode material into a single crystal cathode material comprises:
combining a recycling stream of the nickel-lean cathode material including cathode materials selected from the group consisting of LiMn₂O₄ (LMO) and LiCoO₂ (LCO) with a quantity of NiO based on a target nickel ratio of a recycled cathode material, a quantity of LiOH, and a fluxing agent to form a Li salt mixture, the fluxing agent including additional LiOH and Li₂SO₄;
sintering the Li salt mixture at 900° C. for 10 h with a heating rate of 10° C./min under an oxygen atmosphere; and
rinsing the sintered Li salt mixture to remove excess Li salt to form the single crystal cathode materials having the target nickel ratio.

12. The method of claim 11 wherein the fluxing agent is 20 mol % LiOH and 10 mol % Li₂SO₄.

13. An upcycled, nickel rich recycled cathode material for a recycled battery, comprising:
a granular mass of cathode material particles including charge material elements having a molar ratio of nickel greater than a molar ratio of at least one other metal charge material element,
the granular mass resulting from a recycling stream of a nickel-lean cathode material mixed with additional nickel and a fluxing agent including an excess of Li salts, the additional nickel based on a target nickel ratio for the recycled, nickel rich cathode material; and
the granular mass sintered to form single crystal cathode material having the target nickel ratio and washed for removing the excess lithium resulting from the fluxing agent.

14. The cathode material of claim 13 wherein the single crystal cathode material has a greater percentage of primary particles and a lesser percentage of secondary particles than the nickel lean cathode materials.

15. The cathode material of claim 13 wherein sintering includes heating the salt mixture to form a molten salt defining the fluxing agent, the heating performed a single time for generating the single crystal cathode materials.

16. The cathode material of claim 13 wherein the granular mass from the recycling stream results from:
agitating an end-of-life battery waste stream to generate a particulate mass including casing, current collector, anode material and cathode material;
separating copper and aluminum current collector materials from the particulate mass; and
sieving particles of the nickel-lean cathode material from graphite defining the anode material.

17. The cathode material of claim 13 wherein the recycled cathode material is an upgraded single-crystal form of cathode material from comingled cathode material elements remaining unseparated from constituent metal elements during mixing and sintering.

18. The cathode material of claim 13 further comprising a 622 or 811 Ni, Mn, Co (NMC) formulation and a single crystal morphology, the granular mass having a nickel content <=all other metals in the granular mass prior to mixing.
